(19) United States
(12) Patent Application Publication
(10) Pub. No.: US 2022/0334185 A1
(43) Pub. Date: Oct. 20, 2022

(54) TECHNIQUE FOR ESTIMATION OF INTERNAL BATTERY TEMPERATURE

(71) Applicant: Analog Devices, Inc., Wilmington, MA (US)

(72) Inventors: Omer TANOVIC, Cambridge, MA (US); Frank YAUL, Somerville, MA (US); Hemtej GULLAPALLI, Littleton, MA (US)

(73) Assignee: Analog Devices, Inc., Wilmington, MA (US)

(21) Appl. No.: 17/712,416

(22) Filed: Apr. 4, 2022

Related U.S. Application Data
(60) Provisional application No. 63/174,623, filed on Apr. 14, 2021.
(60) Provisional application No. 63/174,646, filed on Apr. 14, 2021.

(51) Int. Cl. G01R 31/367; H02J 7/00; G01R 31/389; G01R 31/392; G01R 31/382; H01M 10/48

(52) U.S. Cl. CPC G01R 31/367; H02J 7/0048; H02J 7/005; G01R 31/389; G01R 31/392; G01R 31/382; H01M 10/48

(57) ABSTRACT

One embodiment is a method for estimating an internal temperature of a battery, the method comprising obtaining multiple terminal impedance measurements for the battery, wherein each of the terminal impedance measurements is obtained at a different one of a plurality of frequencies; automatically selecting one of a plurality of battery models using on a value of a parameter of the battery, wherein each of the battery models has been trained and corresponds to a different range of values for the battery parameter and wherein the value of the parameter of the battery falls within the range of values for the battery parameter corresponding to the selected one of the plurality of battery models; and applying the selected one of the plurality of battery models to the multiple terminal impedance measurements to estimate the internal temperature of the battery.

### CROSS-REFERENCE TO RELATED APPLICATION

This application claims the benefit of and priority to U.S. Patent Application Ser. No. 63/174,623 filed Apr. 14, 2021, entitled “TECHNIQUE FOR ESTIMATION OF INTERNAL BATTERY TEMPERATURE,” and U.S. Patent Application Ser. No. 63/174,646 filed Apr. 14, 2021, entitled “TECHNIQUE FOR ESTIMATION OF INTERNAL BATTERY TEMPERATURE,” each of which is incorporated herein by reference in its entirety.

### FIELD OF THE DISCLOSURE

This disclosure relates generally to battery temperature monitoring and, more particularly, to a technique for estimating internal temperature of a battery using terminal impedance measurements.

### BRIEF DESCRIPTION OF THE DRAWINGS

To provide a more complete understanding of the present disclosure and features and advantages thereof, reference is made to the following description, taken in conjunction with the accompanying figures, wherein like reference numerals represent like parts, in which:

FIGS. 1A and 1B are simplified diagrams illustrating use of multivariable polynomial regression for estimating the internal temperature of a battery using terminal impedance measurements taken at multiple frequencies of an injected sinusoidal current in accordance with features of embodiments described herein;

FIG. 2 is a flow diagram illustrating operation of a system in which multivariable polynomial regression is used for estimating the internal temperature of a battery using terminal impedance measurements taken at multiple frequencies of an injected sinusoidal current in accordance with features of embodiments described herein;

FIG. 3 is a flow diagram illustrating an example of single measurement factory calibration of a battery model in accordance with features of embodiments described herein;

FIG. 4A is a flow diagram illustrating an alternative embodiment in which singular value decomposition (SVD)-based calibration may be used in connection with techniques for estimating an internal temperature of a battery using impedance measurements in accordance with features of embodiments described herein;

FIG. 4B is a flow diagram illustrating details of SVD calibration for use in connection with techniques for estimating an internal temperature of a battery using impedance measurements in accordance with features of embodiments described herein;

FIG. 5A is a block diagram illustrating an embodiment in which multiple different polynomial regression models may be used for estimating an internal temperature of a battery using impedance measurements in accordance with features of embodiments described herein;

FIG. 5B is a flow diagram illustrating an example operation in which multiple different polynomial regression models may be used for estimating an internal temperature of a battery using impedance measurements in accordance with features of embodiments described herein; and

FIG. 6 is a block diagram of a computer system that may be used to implement all or some portion of the system for estimating an internal temperature of a battery using impedance measurements in accordance with features of embodiments described herein

### DETAILED DESCRIPTION OF EXAMPLE EMBODIMENTS

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. When used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The following disclosure describes various illustrative embodiments and examples for implementing the features and functionality of the present disclosure. While particular components, arrangements, and/or features are described below in connection with various example embodiments, these are merely examples used to simplify the present disclosure and are not intended to be limiting. It will of course be appreciated that in the development of any actual embodiment, numerous implementation-specific decisions must be made to achieve the developer's specific goals, including compliance with system, business, and/or legal constraints, which may vary from one implementation to another. Moreover, it will be appreciated that, while such a development effort might be complex and time-consuming; it would nevertheless be a routine undertaking for those of ordinary skill in the art having the benefit of this disclosure.

In the specification, reference may be made to the spatial relationships between various components and to the spatial orientation of various aspects of components as depicted in the attached drawings. However, as will be recognized by those skilled in the art after a complete reading of the present disclosure, the devices, components, members, apparatuses, etc. described herein may be positioned in any desired orientation. Thus, the use of terms such as “above”, “below”, “upper”, “lower”, “top”, “bottom”, or other similar terms to describe a spatial relationship between various components or to describe the spatial orientation of aspects of such components, should be understood to describe a relative relationship between the components or a spatial orientation of aspects of such components, respectively, as the components described herein may be oriented in any desired direction. When used to describe a range of dimensions or other characteristics (e.g., time, pressure, temperature, length, width, etc.) of an element, operations, and/or conditions, the phrase “between X and Y” represents a range that includes X and Y.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure will now be described with more particular reference to the accompanying FIGURES.

Lithium-ion batteries are rechargeable batteries that are commonly used for portable electronics and electric vehicles (EVs), as well as a variety of other applications, such military and aerospace applications. In order to monitor and maximize the performance of lithium-ion batteries, it is critical to monitor the internal temperature of such batteries during a variety of operations, such as fast charge and rapid discharge operations.

For larger batteries, such as EV batteries, the internal temperature of the battery has previously been monitored using thermal sensors, such as thermocouples, placed on the surface of the battery to monitor the surface temperature of the battery. This solution is non-ideal due to the delay in heat conductivity from the battery's internal core to the surface temperature, as well as the cost and complexity of implementing the necessary thermocouple network in connection with the battery.

For smaller batteries, such as those used in portable electronics such as cellular telephones, electrochemical impedance spectrometry (EIS) may be used to measure battery impedance and internal temperature is estimated using polynomial regression models based on an impedance measurement at a single empirically selected frequency. This solution is also non-ideal given that it does not compensate for battery state-of-health (SOH) or state-of-charge (SOC). Additionally, this method models impedance as a function of frequency and temperature averaged over SOC and has a high computational cost, given that it needs to solve an optimization problem at every step.

In accordance with features of embodiments descried herein, the internal temperature of a rechargeable battery, such as a lithium-ion battery, may be estimated using terminal impedance measurements made at multiple frequencies. The terminal impedance measurements may be combined using multivariable polynomial regression thereby to reduce the effects of state-of-charge (SOC) and state-of-health (SOH) variation on the temperature estimate as compared to estimates based on terminal impedance measurements made at a single frequency.

In one embodiment, an internal temperature estimate may include the weighted sum of polynomial functions of the phases of the impedance measured at each of several predetermined frequencies, which predetermined frequencies may be elected to span a range over which there is sufficient temperature-, SOC-, and SOH-dependence variation to allow the weighted sum to work toward “canceling out” the impact of SOC and SOH variation on the final temperature estimate. In certain embodiments, the equation comprising the regression model may be a linear function of its unknown parameters (e.g., the weights in the sum), such that the model parameters may be fit at low computational cost using linear least squares. Embodiments described herein may also have a relatively low computational cost, enabling the algorithm to be executed on embedded systems and/or processors. In certain embodiments, the regression equation may be augmented with additional terms, such as polynomial functions of cell capacity or terminal voltage, or cross-terms comprising the product of any aforementioned term. The unknown parameters of the regression equation may be calibrated based on prior measurements. For example, a database, or library, of pre-fit battery models may be created and the nearest-neighbor model for a battery may be selected based on a “factory calibration” impedance measurement made when the battery is at specified known conditions.

Embodiments described herein enable a lower-cost, less-intrusive battery temperature monitoring solution as compared with surface-mounted thermocouples. Additionally, as compared with other battery temperature estimation techniques that use polynomial regression based on an impedance measurement at a single frequency, embodiments described herein enable lower computational cost, require fewer model parameters, and provide the ability to reduce or cancel out the effects of SOH and SOC variation on temperature estimation. Additionally terminal voltage and/or cell capacity measurements may be added as inputs to the regression equation to further reduce the effects of SOH and SOC on the temperature estimate.

Monitoring of internal battery temperature is critical for improving battery performance. Monitoring enables maintenance of cell temperature within prescribed boundaries or ranges (maximum and minimum) during fast charging, limitation of current to avoid overheating during rapid discharge, and prevention of damage to a battery due to abnormal usage to ensure safety.

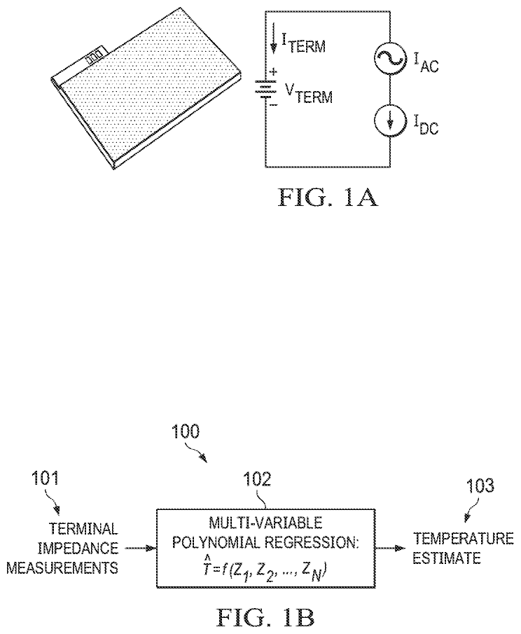

As previously noted, and as generally illustrated in FIG. 1A, in accordance with features of embodiments described herein, multivariable polynomial regression is used to estimate the internal temperature of a battery (such as a lithium-ion battery) using terminal impedance measurements taken at multiple frequencies of an injected sinusoidal current. In certain embodiments, the frequencies for use are identified based on a type of battery. For a given battery type, different frequencies have different temperature-, SOC-, and SOH-dependencies; therefore, multiple frequencies having different such dependencies are ideally selected. As a result, the estimation system is less sensitive to the exact frequencies used as compared to single-frequency regression techniques.

FIG. 1B illustrates a block diagram of a system 100 for using multivariable polynomial regression to estimate the internal temperature of a battery from impedance measurements at multiple frequencies in accordance with one embodiment. As shown in FIG. 1B, terminal impedance measurements taken at a variety of frequencies (designated in FIG. 1B by a reference numeral 101) are input to a multivariable polynomial regression module 102, the output of which is an internal battery temperature estimate. In accordance with features of embodiments described herein, the module 102 implements a multivariable polynomial regression equation that combines the received terminal impedance measurements 101 in a manner that cancels out SOC- and SOH-dependencies to produce an internal temperature estimate 103. No optimization during estimation is required. As described in greater detail below, in some embodiments, the regression equation implemented by the module 102 may be calibrated to a particular battery instance using a small set of measurements from the battery.

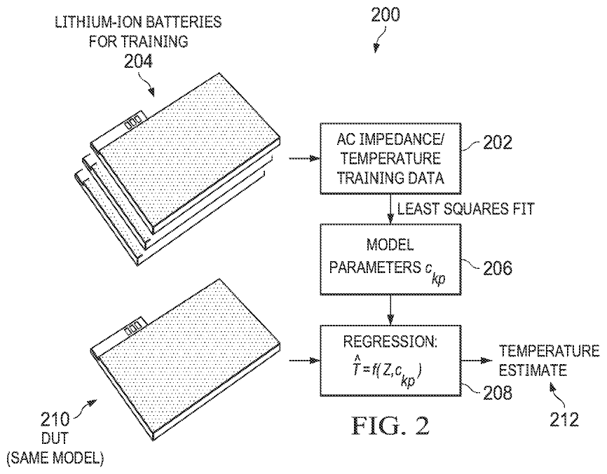

FIG. 2 is a flowchart 200 illustrating operation of the system 100. In step 202, a number of batteries 204 are used to generate training data comprising AC impedance and temperature data. During training, the batteries 204 are cycled many times at a constant current, with temperature varying between cycles and AC impedance (Z) being measured during discharge. In step 206, model parameters (c₀, cₖₚ) are empirically fit using linear least squares applied to the training data accumulated in step 202. The model parameters generated in step 206 are used in a regression equation in step 208, which regression equation is applied to terminal impedance measurements of a device under test (DUT) 210 (which is the same model as the batteries 204) at multiple frequencies f to estimating an internal temperature 212 of the DUT.

In one embodiment, the multivariable polynomial regression equation may be expressed as follows:

$$\hat{T} = {c}_{0} + {\sum }_{k = 0}^{K} {\sum }_{p = 1}^{P} {{c}_{kp} ( ϕ [ k ] )}^{p}$$

The temperature T is estimated using a multivariable polynomial regression on Z phase measurements ϕ[k] where k is the frequency index. In certain embodiments, the multivariable polynomial regression is a third order polynomial regression using multiple frequencies k (e.g., 20 Hz, 60 Hz, and 200 Hz) selected to cancel out SOC- and SOH-dependencies, and 10 learned parameters.

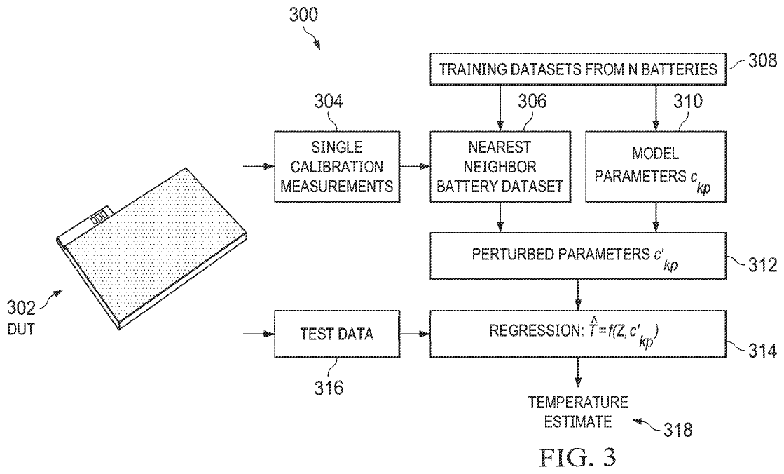

FIG. 3 illustrates a flow diagram 300 showing an example of single measurement factory calibration of a DUT comprising a battery 302. It will be recognized that, although single measurement calibration is shown and described, multiple measurement calibration may be implemented depending on the implementation. As shown in FIG. 3, a single calibration measurement comprising one set of impedance measurements taken at the beginning of the life of the DUT 302 under known conditions (e.g., 25 degrees C., 100% SOC) is taken in step 304. In step 306, a nearest-neighbor dataset in a dataset library 308, which includes training datasets from N batteries, is identified, e.g., using the least squared distance between the initial impedance measurements taken at the known conditions.

In step 310, model parameters cₖₚ are also obtained from the dataset library 308. In step 312, the model parameters obtained in step 310 are perturbed to fit the nearest-neighbor dataset 306 as follows:
1. Tᵣₑₛ=ƒ(Z, cₖₚ)−Tₜᵣᵤₑ
2. Fit (Tᵣₑₛ, Z) dataset using the same polynomial model, with L2 regularization:

$${T}_{res} = {d}_{0} + {\sum }_{k , p} {{d}_{kp} ( ϕ [ k ] )}^{p}$$

3. c′ₖₚ=cₖₚ−dₖₚ

The perturbed parameters cₖₚ′ are used in the regression model 314 applied to test data 316 (i.e., impedance measurements) obtained from the DUT 302 to generate a temperature estimate 318.

In accordance with features of embodiments described herein, other inputs, such as terminal voltage (Vₜₑᵣₘ) may be added to the regression equation. For example, Vₜₑᵣₘ (or other real-valued measurements) may simply be appended to the list of phase measurementsϕ[k], which is equivalent to:

$$\hat{T} = {c}_{0} + {\sum }_{k , p} {{c}_{kp} ( ϕ [ k ] )}^{p} + {\sum }_{n} {c}_{n} {V}_{term}^{n}$$

Vₜₑᵣₘ may compensate for SOC dependence; charge capacity Qₜₒₜ may also be added in a similar manner to compensate for SOH dependence.

Additionally, higher-order cross-terms may be added into the regression equation; for example:

$$\hat{T} = {c}_{0} + {\sum }_{k , p} {{c}_{kp} ( ϕ [ k ] )}^{p} + {\sum }_{θ = ( {k}_{1} , {k}_{2} , {p}_{1} , {p}_{2} )} {{c}_{θ} ( ϕ [ {k}_{1} ] )}^{{p}_{1}} {( ϕ [ {k}_{2} ] )}^{{p}_{2}}$$

Cross-terms may be limited to p₁=₂=1. Additionally, cross-terms may be used with Vₜₑᵣₘ or other real-valued measurements as described above.

As described herein, using multivariable polynomial regression to estimate temperature directly from terminal impedance measurements (and optionally other measurements such as terminal voltage and cell capacity) provides improved accuracy over a single measurement taken at a single frequency and operates to cancel the influence of SOH and SOC due to the fact that the influence of SOH and SOC varies with frequency. Additionally, terminal voltage may be used in order to improve estimates at low SOC. Still further, embodiments described herein are less sensitive to exactly what frequencies are used; therefore, there is no need to identify an “optimal” frequency with minimal SOH and SOC dependence.

Moreover, embodiments described herein do not require whole frequency sweep, thereby enabling reduced measurement time; remain linear-in-coefficients to allow for a linear least squares solution; and require a low number of parameters, thereby reducing the amount of data needed to fit.

In the calibration method shown in and described with reference to FIG. 3, the distance metric dᵢ between the library dataset i and the calibration data is defined as the squared distance between initial impedance measurements taken at known conditions:

dᵢ=|z_{cal}−z_{lib,i}|²

where z_{cal} is the impedance from the single calibration measurement, and z_{lib,i} is the impedance from the ith dataset in the dataset library. Both z_{cal} and z_{lib,i} are measured at the same operating conditions (e.g., same temperature, same SOC, similar SOH).

Alternatively, to determine the nearest-neighbor dataset in a dataset library, instead of defining the distance metric dᵢ as the squared distance between impedance measurements, dᵢ may be defined as the mean square error (MSE) that a perturbed model i achieves on the calibration dataset:

$${d}_{i} = {\sum }_{j} {( f ( {z}_{c a l , j} , {c}_{kp , i}^{′} ) - {T}_{c a l , j} )}^{2}$$

where Z_{cal,j} and T_{cal,j} represent the impedance and temperature of datapoint j in the calibration dataset. The calibration dataset could contain just one datapoint, or multiple datapoints, depending on what is available in the use case. c′_{kp,i} represents the model coefficients that are perturbed to better fit dataset i in the dataset library, as described above. ƒ(z_{cal,j}, c′_{kp,i}) represents the perturbed model with coefficients c′_{kp,i} applied to input data z_{cal,j} to yield a temperature estimate. Note that ƒ(z_{cal,j}, c′_{kp,i}) is not limited to having the input data be only impedance; the input data can include other measurements or estimates (e.g. voltage, SOC, capacity) and the regression equation can include other terms (e.g. voltage, SOC, capacity, cross-terms) as previously described. In general, other distance metrics dᵢ may be used to determine the nearest-neighbor dataset based on the calibration data.

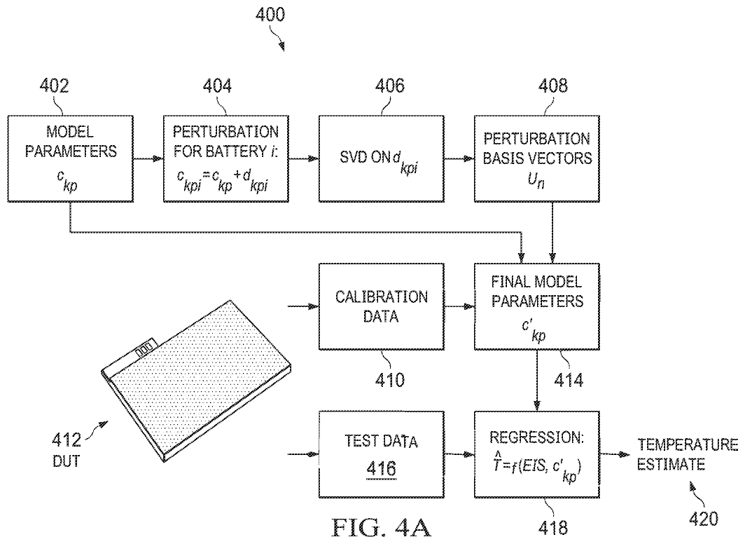

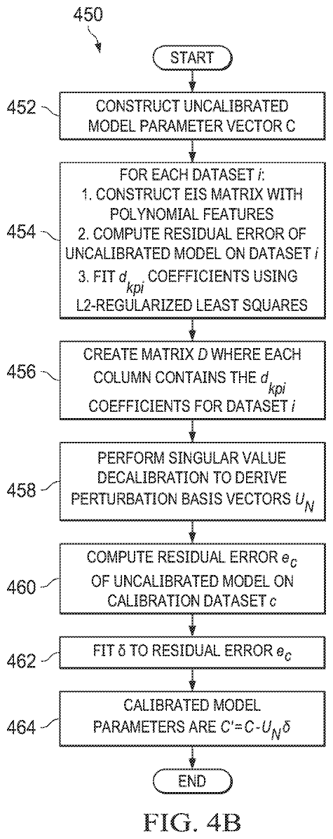

Referring to FIG. 4A, in an alternative embodiment, singular value decomposition (SVD)-based calibration may be used, as illustrated in a flowchart 400. Using the existing training dataset, model parameters are obtained (step 402) and perturbations are determined for each battery that improve the fit (step 404). SVD is applied to the model perturbations (step 406) to determine perturbation basis vectors bₙ (step 408) that can be used to better fit a calibration dataset 410 for a DUT 412 to develop final model parameters (step 414) to be applied to the regression model.

In step 416, the regression model is applied to test data 418 for the DUT 412 to develop a temperature estimate 420.

In accordance with features of embodiments described herein, other inputs, such as battery state-of-charge (SOC) may be added to the regression equation. These inputs do not have to be measured directly, like other real-valued measurements (such as, battery terminal voltage) from the battery or other parts of the system that include the battery. For example, battery state-of-charge SOC may simply be appended to the list of phase measurements ϕ[k], which is equivalent to:

$$\hat{T} = {c}_{0} + {\sum }_{k , p} {{c}_{kp} ( ϕ [ k ] )}^{p} + {\sum }_{q} {c}_{q} {SOC}^{q} .$$

In accordance with features of embodiments described herein, other inputs, such as functions of other real-valued battery measurements, may be added to the regression equation. For example, let function ƒ(·) describe the map from terminal voltage to an estimate of SOC, that is SOC=ƒ(Vₜₑᵣₘ). Then input ƒ(Vₜₑᵣₘ ) may simply be appended to the list of phase measurements ϕ[k], which is equivalent to:

$$\hat{T} = {c}_{0} + {\sum }_{k , p} {{c}_{kp} ( ϕ [ k ] )}^{p} + {\sum }_{r} {c}_{r} {f ( {V}_{term} )}^{r} .$$

Additionally, memory terms can be added to the regression equation. For example, past temperature estimates, past input variables, or cross-terms with these memory terms can be added. For example, when history of phase measurements ϕ[k],ϕ[k−1], . . . ,ϕ[k−M]are used, the regression equation may have the following memory terms

$$\hat{T} = {c}_{0} + {\sum }_{m = 0}^{M} {\sum }_{k , p} {{c}_{kpm} ( ϕ [ k - m ] )}^{p} + {\sum }_{θ = ( {k}_{1} , {k}_{2} , {p}_{1} , {p}_{2} , {m}_{1} , {m}_{2} )} {{c}_{θ} ( ϕ [ {k}_{1} - {m}_{1} ] )}^{{p}_{1}} {( ϕ [ {k}_{2} - {m}_{2} ] )}^{{p}_{2}}$$

In certain embodiments, only immediate past measurements of impedance phase are used which corresponds to the memory depth parameter M=1.

Referring now to FIG. 4B, in one embodiment, SVD calibration may be performed as illustrated in a flow diagram 450. First, in step 452, an uncalibrated model parameter vector C containing the model parameters cₖₚ is constructed. In step 454, for each dataset i: (1) the EIS matrix Zᵢ is constructed with polynomial features (rows are datapoints, columns are features); (2) the residual error eᵢ of the uncalibrated model on dataset i is computed using the equation eᵢ=ZᵢC−T_{true,i}; and (3) dₖₚᵢ is fit using L2-regularized least squares (eᵢ≈Zᵢdₖₚᵢ).

In step 456, a matrix D is created in which each column contains the dₖₚ coefficients for dataset i. In step 458, SVD is then performed on dₖₚᵢ as follows: (1) define D as D=UΣV^{T}; (2) take the N most significant singular vectors from U and define them as perturbation basis vectors U_{N}. In step 460, the residual error of the uncalibrated model on the calibration dataset c is computed using the equation e_{c}Z_{c}C−T_{true,c}. In step 462, δ is fit to e_{c} using the equation e_{c}≈Z_{C}U_{N}δ. In step 464, the resulting calibrated model parameters C′ are equal to C−U_{nδ}.

In some embodiments described herein, δ represents the weights or coefficients applied to the basis vectors U_{N} to create the perturbation vector to be applied to the model parameters or coefficients C. The basis vectors U_{N} represent the typical ways that the model coefficients vary from battery to battery. δ is found using calibration data in order to determine how much of each basis vector should be used the perturb the model to better fit the calibration dataset.

When a battery is in steady-state (i.e., internal temperature similar to external temperature), a calibration measurement (Z, T) can be taken. Such calibration measurements may be accumulated over the lifetime of a battery to form the overall calibration dataset. Alternatively, a specific time window from the historical data may be used. Temperature estimation parameters can be recalibrated from this dataset using SVD calibration, as described above.

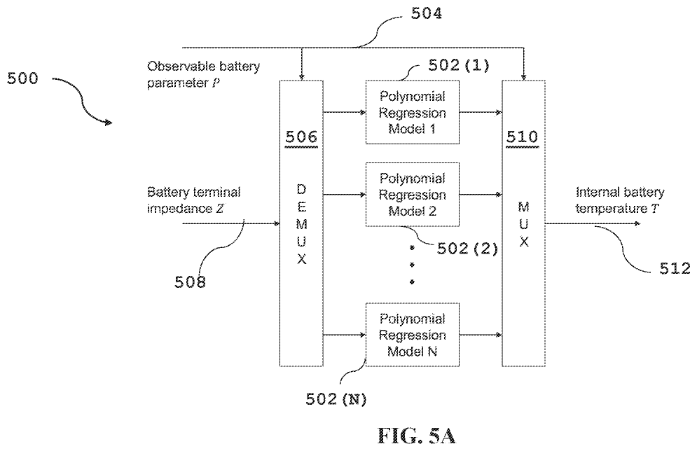

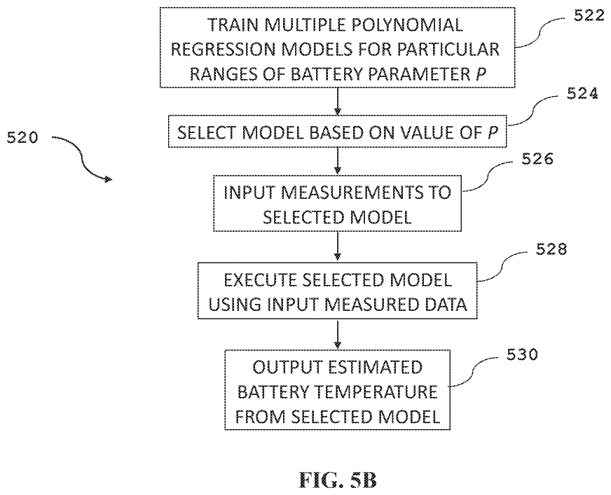

FIG. 5A is a block diagram illustrating an embodiment of a system 500 in which multiple different polynomial regression models 502(1)-502(N) (similar to the model 314 (FIG. 3)) may be used to estimate an internal temperature T of a battery. In accordance with features of embodiments described herein, each of the polynomial regression models 502 is trained on data comprising measurements made for a different range of values of a selected measurable (directly or indirectly) battery parameter P. In certain embodiments, the battery parameter P may be the battery SOH (capacity) or battery SOC, for example. The value of the parameter P is used as a control signal 504 for an 1×N demultiplexer (DEMUX) 506 having N outputs connected to inputs of the N pre-trained polynomial regression models 502. In operation, a signal corresponding to a measured value (for example, battery terminal impedance, as shown in FIG. 5A) input 508 to the DEMUX 506 is switched by the DEMUX under the control of the value of battery parameter P on the control signal line 504 (which is connected to a SELECT input of the DEMUX) to the corresponding one of the pre-trained polynomial regression models 502. In accordance with features of embodiments described herein, parameters of the selected one of the models 502 have been pre-fit using data that corresponds to the designated range of values for P.

For example, in a case in which P represents the remaining battery capacity, the range for model 502(1) may be selected to correspond to 100% to 95% of the nominal battery capacity, the range for model 502(2) may be selected to correspond to 95% to 90% of the nominal battery capacity, and so on. In this example, if the value of control signal 504 of the DEMUX 506 (i.e., the parameter P) is within the interval (90%,95%) then the input signal 508 will be passed to regression model 502(2).

Correspondingly, an N×1 multiplexer (MUX) 510 having N inputs connected to outputs of the models 502 is also controlled by the parameter P (i.e., the control line 504 is connected to a SELECT input of the MUX 510) such that an internal battery temperature estimate signal T output 512 from the MUX 510 comprises the output of the model 502 to which the parameter P corresponds (again, in the example above, the model 502(2)).

In certain embodiments, model selection may be triggered by more than one parameter. For example, classification of models used for temperature estimation may be accomplished by parsing the full range of both SOC and SOH metrics. In this case, the observable battery parameter P used as control signal 504 may be a 2-dimensional vector [P1,P2], where the first component P1 may correspond to the SOH metric and the second component P2 may correspond to the SOC metric. In this case, the DEMUX 506 would be implemented as an (NM)×1 demultiplexer and the MUX 510 would be implemented as an (NM)×1 multiplexer. Additionally, the group of models 502 would include NM models corresponding to N different ranges for remaining battery capacity (SOH) and M different ranges for battery state of charge (SOC). For example, the range for a first model , designated model [1, 1] may be selected to correspond to 100% to 95% of the nominal battery capacity and 100% to 90% of the battery state-of-charge, the range of a second model (model [1, 2]) may be selected to correspond to 100% to 95% of the nominal battery capacity and 90% to 80% of the battery state-of-charge, and so on, until the range of a tenth model (model [1, 10]) may be selected to correspond to 100% to 95% of the nominal battery capacity and 10% to 0% of the battery state-of-charge. In this example, if the values of control signal 504 of the DEMUX 506 (i.e., the parameter P=[P1,P2]) are within the interval (90%,95%) for P1 and (20%,10%) for P2, then the input signal 508 will be passed to a corresponding model (e.g., a ninth model (model [1, 9] , using the numbering convention established in the foregoing example).

Additionally, model parameters learned using data from a first type of battery can be used to estimate temperature for a second (different) type of battery. In one embodiment, this may be accomplished by calibration of the model parameters of model 502, trained on battery data from the first type of battery, using impedance measurements of the targeted second type of battery. In another embodiment, this may be accomplished by first training a predistortion model, which transforms impedance measurements of the second type of battery into an impedance value of the first type of battery for which the model 502 was trained. Output of this predistortion model may then be fed into model 502 to generate an estimate of the internal temperature of the second type of battery. Parameters of the predistortion model may be trained on a small set of impedance measurement data of the second type of battery that is sufficient to train the predistortion model but not large enough to train a corresponding model 502 from scratch. The predistortion model may have other inputs besides battery impedance measurement, such as SOC and SOH metrics.

FIG. 5B is a flow diagram 520 illustrating an example operations for using multiple different polynomial regression models to estimate an internal temperature of a battery using impedance measurements in accordance with features of embodiments described herein.

In step 522, multiple polynomial regression models may be trained as described above. In accordance with features of embodiments described herein, each of the models is trained on data comprising measurements made for a different range of values of a selected measurable (directly or indirectly) battery parameter P.

In step 524, one of the models is selected based on the value of the battery parameter P. In particular, the model corresponding to the range of values in which P falls is selected.

In step 526, the measured data is input to the selected model. In particular, in certain embodiments, the measured terminal impedance data is input to the selected model.

In step 528, the selected model executes on the measured data input thereto.

In step 530, the estimated battery temperature is output from the selected model.

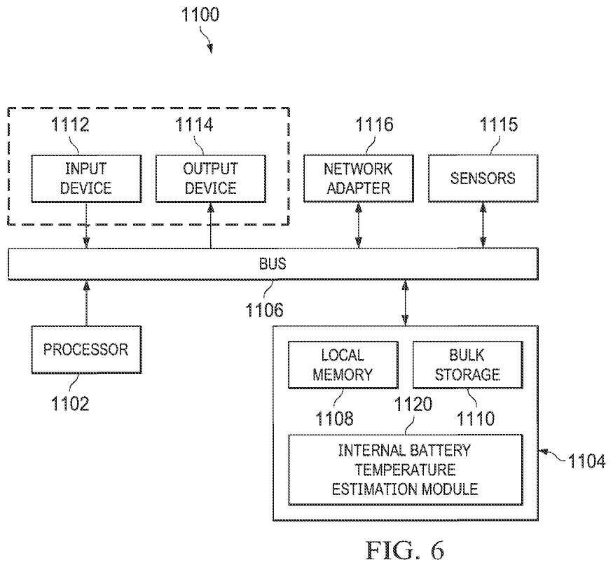

FIG. 6 is a block diagram illustrating an example system 1100 that may be configured to implement at least portions of techniques for internal battery temperature estimation using impedance measurements in accordance with embodiments described herein, and more particularly as shown in the FIGURES described hereinabove. As shown in FIG. 6, the system 1100 may include at least one processor 1102, e.g., a hardware processor 1102, coupled to memory elements 1104 through a system bus 1106. As such, the system may store program code and/or data within memory elements 1104. Further, the processor 1102 may execute the program code accessed from the memory elements 1104 via a system bus 1106. In one aspect, the system may be implemented as a computer that is suitable for storing and/or executing program code. It should be appreciated, however, that the system 1100 may be implemented in the form of any system including a processor and a memory that is capable of performing the functions described in this disclosure.

In some embodiments, the processor 1102 can execute software or an algorithm to perform the activities as discussed in this specification; in particular, activities related to internal battery temperature estimation using impedance measurements in accordance with embodiments described herein. The processor 1102 may include any combination of hardware, software, or firmware providing programmable logic, including by way of non-limiting example a microprocessor, a DSP, a field-programmable gate array (FPGA), a programmable logic array (PLA), an integrated circuit (IC), an application specific IC (ASIC), or a virtual machine processor. The processor 1102 may be communicatively coupled to the memory element 1104, for example in a direct-memory access (DMA) configuration, so that the processor 1102 may read from or write to the memory elements 1104.

In general, the memory elements 1104 may include any suitable volatile or non-volatile memory technology, including double data rate (DDR) random access memory (RAM), synchronous RAM (SRAM), dynamic RAM (DRAM), flash, read-only memory (ROM), optical media, virtual memory regions, magnetic or tape memory, or any other suitable technology. Unless specified otherwise, any of the memory elements discussed herein should be construed as being encompassed within the broad term “memory.” The information being measured, processed, tracked, or sent to or from any of the components of the system 1100 could be provided in any database, register, control list, cache, or storage structure, all of which can be referenced at any suitable timeframe. Any such storage options may be included within the broad term “memory” as used herein. Similarly, any of the potential processing elements, modules, and machines described herein should be construed as being encompassed within the broad term “processor.” Each of the elements shown in the present figures may also include suitable interfaces for receiving, transmitting, and/or otherwise communicating data or information in a network environment so that they can communicate with, for example, a system having hardware similar or identical to another one of these elements.

In certain example implementations, mechanisms for implementing internal battery temperature estimation using impedance measurements as outlined herein may be implemented by logic encoded in one or more tangible media, which may be inclusive of non-transitory media, e.g., embedded logic provided in an ASIC, in DSP instructions, software (potentially inclusive of object code and source code) to be executed by a processor, or other similar machine, etc. In some of these instances, memory elements, such as e.g., the memory elements 1104 shown in FIG. 6 can store data or information used for the operations described herein. This includes the memory elements being able to store software, logic, code, or processor instructions that are executed to carry out the activities described herein. A processor can execute any type of instructions associated with the data or information to achieve the operations detailed herein. In one example, the processors, such as e.g., the processor 1102 shown in FIG. 6, could transform an element or an article (e.g., data) from one state or thing to another state or thing. In another example, the activities outlined herein may be implemented with fixed logic or programmable logic (e.g., software/computer instructions executed by a processor) and the elements identified herein could be some type of a programmable processor, programmable digital logic (e.g., an FPGA, a DSP, an erasable programmable read-only memory (EPROM), an electrically erasable programmable read-only memory (EEPROM)) or an ASIC that includes digital logic, software, code, electronic instructions, or any suitable combination thereof.

The memory elements 1104 may include one or more physical memory devices such as, for example, local memory 1108 and one or more bulk storage devices 1110. The local memory may refer to RAM or other non-persistent memory device(s) generally used during actual execution of the program code. A bulk storage device may be implemented as a hard drive or other persistent data storage device. The processing system 1100 may also include one or more cache memories (not shown) that provide temporary storage of at least some program code in order to reduce the number of times program code must be retrieved from the bulk storage device 1110 during execution.

As shown in FIG. 6, the memory elements 1104 may store an internal battery temperature estimation module 1120. In various embodiments, the module 1120 may be stored in the local memory 1108, the one or more bulk storage devices 1110, or apart from the local memory and the bulk storage devices. It should be appreciated that the system 1100 may further execute an operating system (not shown in FIG. 6) that can facilitate execution of the module 1120. The module 1120, being implemented in the form of executable program code and/or data, can be read from, written to, and/or executed by the system 1100, e.g., by the processor 1102. Responsive to reading from, writing to, and/or executing the module 1120, the system 1100 may be configured to perform one or more operations or method steps described herein.

Input/output (I/O) devices depicted as an input device 1112 and an output device 1114, optionally, may be coupled to the system. Examples of input devices may include, but are not limited to, a keyboard, a pointing device such as a mouse, or the like. Examples of output devices may include, but are not limited to, a monitor or a display, speakers, or the like. In some implementations, the system may include a device driver (not shown) for the output device 1114. Input and/or output devices 1112, 1114 may be coupled to the system 1100 either directly or through intervening I/O controllers. Additionally, sensors 1115, may be coupled to the system 1100 either directly or through intervening controllers and/or drivers.

In an embodiment, the input and the output devices may be implemented as a combined input/output device (illustrated in FIG. 6 with a dashed line surrounding the input device 1112 and the output device 1114). An example of such a combined device is a touch sensitive display, also sometimes referred to as a “touch screen display” or simply “touch screen.” In such an embodiment, input to the device may be provided by a movement of a physical object, such as e.g., a stylus or a finger of a user, on or near the touch screen display.

A network adapter 1116 may also, optionally, be coupled to the system 1100 to enable it to become coupled to other systems, computer systems, remote network devices, and/or remote storage devices through intervening private or public networks. The network adapter may comprise a data receiver for receiving data that is transmitted by said systems, devices and/or networks to the system 1100, and a data transmitter for transmitting data from the system 1100 to said systems, devices and/or networks. Modems, cable modems, and Ethernet cards are examples of different types of network adapter that may be used with the system 1100.

Example 1 is method for estimating an internal temperature of a battery, the method comprising obtaining multiple terminal impedance measurements for the battery, wherein each of the terminal impedance measurements is obtained at a different one of a plurality of frequencies; automatically selecting one of a plurality of battery models using a value of a parameter of the battery, wherein each of the battery models has been trained and corresponds to a different range of values for the battery parameter and wherein the value of the parameter of the battery falls within the range of values for the battery parameter corresponding to the selected one of the plurality of battery models; and applying the selected one of the plurality of battery models to the multiple terminal impedance measurements to estimate the internal temperature of the battery.

Example 2 provides the method of example 1, wherein each of the battery models comprises a multivariable polynomial regression model.

Example 3 provides the method of example 2, further comprising determining model parameters for the selected multivariable polynomial regression model.

Example 4 provides the method of example 3, wherein the determining model parameters comprises obtaining training data from a plurality of batteries; and applying a linear least squares fit to the training data.

Example 5 provides the method of example 4, wherein the training data comprises AC impedance and temperature data.

Example 6 provides the method of example 5, further comprising, calibrating the model parameters using at least one calibration measurement associated with the battery.

Example 7 provides the method of any of examples 1-6, wherein the battery comprises a rechargeable battery.

Example 8 provides the method of example 7, wherein the battery comprises a lithium-ion battery.

Example 9 provides the method of any of examples 1-8, wherein the frequencies are selected in order to cancel out at least one of state-of-charge (SOC) and state-of-health (SOH) dependencies.

Example 10 provides the method of any of examples 1-9, wherein the battery parameter comprises at least one of a state-of-health (SOH) and a state-of-charge (SOC).

Example 11 provides the method of any of Examples 1-10, wherein the battery parameter comprises multiple battery parameters.

Example 12 provides the method of any of examples 1-11, further comprising augmenting an equation comprising at least one of the models by adding a function of another measurement of the battery to the equation.

Example 13 provides the method of any of examples 1-12, further comprising augmenting an equation comprising at least one of the models to include a memory term.

Example 14 provides a method for estimating an internal temperature of a battery under test (BUT) from terminal impedance measurements of the BUT, the method comprising obtaining multiple terminal impedance measurements for the BUT at a plurality of frequencies; automatically selecting one of a plurality of multivariable polynomial regression models using a value of a parameter of the but, wherein each of the multivariable polynomial regression models corresponds to a different range of values for the battery parameter and wherein the value of the parameter of the BUT falls within the range of values for the battery parameter corresponding to the selected one of the plurality of multivariable polynomial regression models; deriving model parameters for a selected one of a plurality of multivariable polynomial regression models, the deriving comprising obtaining training data from the set of training batteries; and applying a linear least squares fit to the training data; and combining the multiple terminal impedance measurements using the selected one of the multivariable polynomial regression models to produce an estimate of the internal temperature of the BUT.

Example 15 provides the method of example 14, wherein the set of training batteries is comprised of individual batteries of a same type as the BUT.

Example 16 provides the method of any of examples 14-15, wherein the set of training batteries is comprised of individual batteries of a different type than the BUT, the method further comprising calibrating the derived model parameters prior to the combining.

Example 17 provides the method of examples 16, wherein the set of training batteries is comprised of individual batteries that are different than the BUT, the method further comprising mapping the derived model parameters to a second set of model parameters corresponding to the battery under test prior to the combining.

Example 18 provides the method of any of examples 14-17, wherein the battery comprises a rechargeable battery.

Example 19 provides the method of any of examples 14-18, wherein the battery parameter comprises at least one of a state-of-health (SOH) and a state-of-charge (SOC).

Example 20 provides the method of any of examples 14-19, wherein the battery parameter comprises multiple battery parameters.

Example 21 provides the method of any of examples 14-20, further comprising augmenting an equation comprising at least one of the multivariable polynomial regression models by adding a function of another measurement of the battery to the equation.

Example 22 provides the method of any of examples 14-21, further comprising augmenting an equation comprising at least one of the multivariable polynomial regression models to include a memory term.

Example 23 provides a system for estimating an internal temperature of a battery from a plurality of terminal impedance measurements obtained for the battery, wherein the terminal impedance measurements are taken at a plurality of frequencies, the system comprising N polynomial regression models; circuitry for automatically selecting one of the N polynomial regression models using a value of a parameter of the battery, wherein each of the polynomial regression models has been trained and corresponds to a different range of values for the battery parameter and wherein the value of the parameter of the battery falls within the range of values for the battery parameter corresponding to the selected one of the N polynomial regression models; wherein the selected one of the N polynomial regression models combines the multiple terminal impedance measurements to generate an estimate the internal temperature of the battery.

Example 24 provides the system of example 23, wherein the battery comprises a rechargeable battery.

Example 25 provides the system of any of examples 23-24, wherein the battery parameter comprises at least one of a battery state-of-health (SOH) and a battery state-of-charge (SOC).

Example 26 provides the system of any of examples 23-25, wherein the battery parameter comprises a plurality of battery parameters.

Example 27 provides the system of any of examples 23-26, wherein the circuitry comprises a demultiplexer (DEMUX) having an input connected to receive the multiple terminal impedance measurements and N outputs connected to inputs of the N polynomial regression models.

Example 28 provides the system of example 27, wherein a SELECT input of the DEMUX is connected to receive a signal corresponding to the value of the battery parameter.

Example 29 provides the system of any of examples 23-28, wherein the circuitry comprises a multiplexer (MUX) having N inputs connected to receive outputs of the N polynomial regression models and an output for outputting an estimated internal temperature of the battery.

Example 30 provides the system of example 29, wherein a control input of the MUX is connected to receive a signal corresponding to the value of the battery parameter.

It should be noted that all of the specifications, dimensions, and relationships outlined herein (e.g., the number of elements, operations, steps, etc.) have only been offered for purposes of example and teaching only. Such information may be varied considerably without departing from the spirit of the present disclosure, or the scope of the appended claims. The specifications apply only to one non-limiting example and, accordingly, they should be construed as such. In the foregoing description, exemplary embodiments have been described with reference to particular component arrangements. Various modifications and changes may be made to such embodiments without departing from the scope of the appended claims. The description and drawings are, accordingly, to be regarded in an illustrative rather than in a restrictive sense.

Note that with the numerous examples provided herein, interaction may be described in terms of two, three, four, or more electrical components. However, this has been done for purposes of clarity and example only. It should be appreciated that the system may be consolidated in any suitable manner. Along similar design alternatives, any of the illustrated components, modules, and elements of the FIGURES may be combined in various possible configurations, all of which are clearly within the broad scope of this specification. In certain cases, it may be easier to describe one or more of the functionalities of a given set of flows by only referencing a limited number of electrical elements. It should be appreciated that the electrical circuits of the FIGURES and its teachings are readily scalable and may accommodate a large number of components, as well as more complicated/sophisticated arrangements and configurations. Accordingly, the examples provided should not limit the scope or inhibit the broad teachings of the electrical circuits as potentially applied to myriad other architectures.

It should also be noted that in this specification, references to various features (e.g., elements, structures, modules, components, steps, operations, characteristics, etc.) included in “one embodiment”, “exemplary embodiment”, “an embodiment”, “another embodiment”, “some embodiments”, “various embodiments”, “other embodiments”, “alternative embodiment”, and the like are intended to mean that any such features are included in one or more embodiments of the present disclosure, but may or may not necessarily be combined in the same embodiments.

It should also be noted that the functions related to circuit architectures illustrate only some of the possible circuit architecture functions that may be executed by, or within, systems illustrated in the FIGURES. Some of these operations may be deleted or removed where appropriate, or these operations may be modified or changed considerably without departing from the scope of the present disclosure. In addition, the timing of these operations may be altered considerably. The preceding operational flows have been offered for purposes of example and discussion. Substantial flexibility is provided by embodiments described herein in that any suitable arrangements, chronologies, configurations, and timing mechanisms may be provided without departing from the teachings of the present disclosure.

Numerous other changes, substitutions, variations, alterations, and modifications may be ascertained to one skilled in the art and it is intended that the present disclosure encompass all such changes, substitutions, variations, alterations, and modifications as falling within the scope of the appended claims.

Note that all optional features of the device and system described above may also be implemented with respect to the method or process described herein and specifics in the examples may be used anywhere in one or more embodiments.

The ‘means for’ in these instances (above) may include (but is not limited to) using any suitable component discussed herein, along with any suitable software, circuitry, hub, computer code, logic, algorithms, hardware, controller, interface, link, bus, communication pathway, etc.

Note that with the example provided above, as well as numerous other examples provided herein, interaction may be described in terms of two, three, or four network elements. However, this has been done for purposes of clarity and example only. In certain cases, it may be easier to describe one or more of the functionalities of a given set of flows by only referencing a limited number of network elements. It should be appreciated that topologies illustrated in and described with reference to the accompanying FIGURES (and their teachings) are readily scalable and may accommodate a large number of components, as well as more complicated/sophisticated arrangements and configurations. Accordingly, the examples provided should not limit the scope or inhibit the broad teachings of the illustrated topologies as potentially applied to myriad other architectures.

It is also important to note that the steps in the preceding flow diagrams illustrate only some of the possible signaling scenarios and patterns that may be executed by, or within, communication systems shown in the FIGURES. Some of these steps may be deleted or removed where appropriate, or these steps may be modified or changed considerably without departing from the scope of the present disclosure. In addition, a number of these operations have been described as being executed concurrently with, or in parallel to, one or more additional operations. However, the timing of these operations may be altered considerably. The preceding operational flows have been offered for purposes of example and discussion. Substantial flexibility is provided by communication systems shown in the FIGURES in that any suitable arrangements, chronologies, configurations, and timing mechanisms may be provided without departing from the teachings of the present disclosure.

Although the present disclosure has been described in detail with reference to particular arrangements and configurations, these example configurations and arrangements may be changed significantly without departing from the scope of the present disclosure. For example, although the present disclosure has been described with reference to particular communication exchanges, embodiments described herein may be applicable to other architectures.

Numerous other changes, substitutions, variations, alterations, and modifications may be ascertained to one skilled in the art and it is intended that the present disclosure encompass all such changes, substitutions, variations, alterations, and modifications as falling within the scope of the appended claims. In order to assist the United States Patent and Trademark Office (USPTO) and, additionally, any readers of any patent issued on this application in interpreting the claims appended hereto, Applicant wishes to note that the Applicant: (a) does not intend any of the appended claims to invoke paragraph six (6) of 35 U.S.C. section 142 as it exists on the date of the filing hereof unless the words “means for” or “step for” are specifically used in the particular claims; and (b) does not intend, by any statement in the specification, to limit this disclosure in any way that is not otherwise reflected in the appended claims.

What is claimed is:

1. A method for estimating an internal temperature of a battery, the method comprising:
obtaining multiple terminal impedance measurements for the battery, wherein each of the terminal impedance measurements is obtained at a different one of a plurality of frequencies;
automatically selecting one of a plurality of battery models using a value of a parameter of the battery, wherein each of the battery models has been trained and corresponds to a different range of values for the battery parameter and wherein the value of the parameter of the battery falls within the range of values for the battery parameter corresponding to the selected one of the plurality of battery models; and
applying the selected one of the plurality of battery models to the multiple terminal impedance measurements to estimate the internal temperature of the battery.

2. The method of claim 1, wherein each of the battery models comprises a multivariable polynomial regression model.

3. The method of claim 2, further comprising determining model parameters for the selected multivariable polynomial regression model.

4. The method of claim 3, wherein the determining model parameters comprises:
obtaining training data from a plurality of batteries; and
applying a linear least squares fit to the training data.

5. The method of claim 4, wherein the training data comprises AC impedance and temperature data.

6. The method of claim 5, further comprising, calibrating the model parameters using at least one calibration measurement associated with the battery.

7. The method of claim 1, wherein the battery comprises a rechargeable battery.

8. The method of claim 1, wherein the frequencies are selected in order to cancel out at least one of state-of-charge (SOC) and state-of-health (SOH) dependencies.

9. The method of claim 1, wherein the battery parameter comprises at least one of a state-of-health (SOH) and a state-of-charge (SOC).

10. The method of claim 1, wherein the battery parameter comprises multiple battery parameters.

11. The method of claim 1, further comprising augmenting an equation comprising at least one of the models by adding a function of another measurement of the battery to the equation.

12. The method of claim 1, further comprising augmenting an equation comprising at least one of the models to include a memory term.

13. A method for estimating an internal temperature of a battery under test (BUT) from terminal impedance measurements of the BUT, the method comprising:
obtaining multiple terminal impedance measurements for the BUT at a plurality of frequencies;
automatically selecting one of a plurality of multivariable polynomial regression models using a value of a parameter of the but, wherein each of the multivariable polynomial regression models corresponds to a different range of values for the battery parameter and wherein the value of the parameter of the BUT falls within the range of values for the battery parameter corresponding to the selected one of the plurality of multivariable polynomial regression models;
deriving model parameters for a selected one of a plurality of multivariable polynomial regression models, the deriving comprising:
obtaining training data from the set of training batteries; and
applying a linear least squares fit to the training data; and
combining the multiple terminal impedance measurements using the selected one of the multivariable polynomial regression models to produce an estimate of the internal temperature of the BUT.

14. The method of claim 13, wherein the set of training batteries is comprised of individual batteries of a different type than the BUT, the method further comprising calibrating the derived model parameters prior to the combining.

15. The method of claim 13, wherein the set of training batteries is comprised of individual batteries that are different than the BUT, the method further comprising mapping the derived model parameters to a second set of model parameters corresponding to the battery under test prior to the combining.

16. A system for estimating an internal temperature of a battery from a plurality of terminal impedance measurements obtained for the battery, wherein the terminal impedance measurements are taken at a plurality of frequencies, the system comprising:
N polynomial regression models;
circuitry for automatically selecting one of the N polynomial regression models using a value of a parameter of the battery, wherein each of the polynomial regression models has been trained and corresponds to a different range of values for the battery parameter and wherein the value of the parameter of the battery falls within the range of values for the battery parameter corresponding to the selected one of the N polynomial regression models;
wherein the selected one of the N polynomial regression models combines the multiple terminal impedance measurements to generate an estimate the internal temperature of the battery.

17. The system of claim 16, wherein the circuitry comprises a demultiplexer (DEMUX) having an input connected to receive the multiple terminal impedance measurements and N outputs connected to inputs of the N polynomial regression models.

18. The system of claim 17, wherein a SELECT input of the DEMUX is connected to receive a signal corresponding to the value of the battery parameter.

19. The system of claim 16, wherein the circuitry comprises a multiplexer (MUX) having N inputs connected to receive outputs of the N polynomial regression models and an output for outputting an estimated internal temperature of the battery.

20. The system of claim 19, wherein a control input of the MUX is connected to receive a signal corresponding to the value of the battery parameter.
